(19) United States
(12) Patent Application Publication
(10) Pub. No.: US 2023/0128025 A1
(43) Pub. Date: Apr. 27, 2023

(54) SYSTEMS AND METHODS FOR DECOMPOSED DIGITAL FILTER

(71) Applicant: Intel Corporation, Santa Clara, CA (US)

(72) Inventor: Volker Mauer, Princes Risborough (GB)

(21) Appl. No.: 18/145,002

(22) Filed: Dec. 21, 2022

(51) Int. Cl. G06F 7/02

(52) U.S. Cl. CPC G06F 7/023; G06F 7/768

(57) ABSTRACT

Circuitry, systems, and methods are provided for an integrated circuit that includes digital filter circuitry. The digital filtering circuitry includes a first partial filter that includes a first number of taps corresponding to coefficients of a first bit depth and a second partial filter that includes a second number of taps corresponding to coefficients of a second bit depth.

### BACKGROUND

The present disclosure relates to resource-efficient circuitry of an integrated circuit that can perform filtering using a digital filter decomposed into multiple component filters.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits are found in numerous electronic devices and provide a variety of functionality. Many integrated circuits include arithmetic circuit blocks to perform arithmetic operations such as addition and multiplication. For example, a digital signal processing (DSP) block may supplement programmable logic circuitry in a programmable logic device, such as a field programmable gate array (FPGA). In some integrated circuits, DSP blocks may implement digital filters, such as finite impulse response (FIR) filters. However, FIR filters may take up valuable die area of the integrated circuit and be resource-intensive components.

In certain instances, there may be granularity effects that come from the data widths of the multipliers in the FIR filter. For example, a mathematical description of the FIR filter may include coefficients, the input precision, the coefficient precision, and the desired output precision. To reduce the output length to a desired length, a rounding method may be applied to the mathematical description. For example, DSP processors generally operate with a data width of 16-bits and FPGAs generally operate with a data width of 18-bits. However, the user may desire a data width of 16-bits with the DSP processor and the data width may be mapped onto four 16×16 multipliers. If the coefficients are fixed, then the FIR filter may implement 2×16 multipliers for each term (e.g., if the coefficient is represented by a data width of 16-bits). Such action may cost between 2× and 4×, depending on a number of taps that may use a 16-bit coefficient. Moreover, the output precision may be limited by rounding and saturation.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device, in accordance with an embodiment of the present disclosure;

FIG. 2 is a block diagram of a system used to program the integrated circuit device, in accordance with an embodiment of the present disclosure;

FIG. 3 is a block diagram of a digital filter that may be implemented in digital signal processing (DSP) blocks of the integrated circuit device;

FIG. 4 is a graph illustrating finite impulse response (FIR) filter coefficients over a number of taps, in accordance with an embodiment of the present disclosure;

FIG. 5 is a graph illustrating the FIR filter coefficient bit-widths over a number of taps, in accordance with an embodiment of the present disclosure;

FIG. 6 is a graph illustrating the outer FIR filter coefficients over a number of taps, in accordance with an embodiment of the present disclosure;

FIG. 7 is a graph illustrating the inner FIR filter coefficients over a number of taps, in accordance with an embodiment of the present disclosure;

FIG. 8 in a flow chart of an example method for generating an output using two individual FIR filters, accordance with an embodiment of the present disclosure;

FIG. 9 is a block diagram of a one-tap FIR filter decomposed into four individual FIR filters, for in accordance with an embodiment of the present disclosure;

FIG. 10 is a block diagram of a general FIR filter decomposed into four individual FIR filters, in accordance with an embodiment of the present disclosure;

FIG. 11 is a flow chart of an example method of a FIR implementation tool generating four individual FIR filters, in accordance with an embodiment of the present disclosure; and

FIG. 12 is a block diagram of a data processing system that may incorporate the integrated circuit with a decomposed digital filter, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

Digital filters, such as finite impulse response (FIR) filters, are used in many digital signal processing (DSP) applications. For example, FIR filters can be found in wireless communication systems with digital signal processing elements, such as radio cards for 5G communication systems. It is presently recognized that FIR filters are large filters that consume a significant amount of hardware resources and power.

Embodiments of the present disclosure include a digital filter, such as a FIR filter, that may be decomposed into two or more filters. This may reduce an amount of power consumed by operating the FIR filter or given a fixed bit-width, decomposing the FIR filter allows the use more taps to improve output precision when using the same resources. For example, a DSP block of an integrated circuit may use a first FIR filter processing outer coefficients and a second FIR filter processing inner coefficients. In another example, the FIR filter may use n-bits for data and coefficients; however, when decomposed into four individual filters (e.g., partial filter, sub-filter), each decomposed filter may instead use n/2 bits. Each of the four decomposed filters may operate at a lower input and coefficient precision. Additionally or alternatively, each decomposed filter may be optimized independently, thereby improving precision of the overall FIR filter. The decomposed filters may be optimized using the bit-widths of the individual coefficients and the sub-filter's contribution to the output. In another example, the FIR filter may be decomposed into a first partial filter that may be a long filter (e.g., full number of taps), a second partial filter that may be a short filter (e.g., reduced number of taps), and a third partial filter that may be a short filter, and a fourth partial filter that may be either a long filter or a short filter. In certain instances, the fourth partial filter may be optimized away, thereby reducing power consumed by operating the FIR filter.

When implemented in DSPs applications, using the reduced number of multipliers may reduce a cycle count. In certain instances, DSP processing chains operate around the 16-bit precision. For example, the DSP processing chain may use an 8-bit precision. As such, decomposition of the original 16-bit FIR filter into four 8-bit FIR filters may allow the FIR filters to be efficiently implemented into a wide range of DSP applications. Moreover, FIR filters have become so dominant in DSP applications that specialized DSP blocks have been added to FPGAs with specific features for implementing the FIR filters (e.g., pre-adders). As such, a reduced number of multipliers may save FPGA resources. For example, less energy may be consumed since fewer FPGA resources are being used. In certain instances, a size of the FPGA may be reduced.

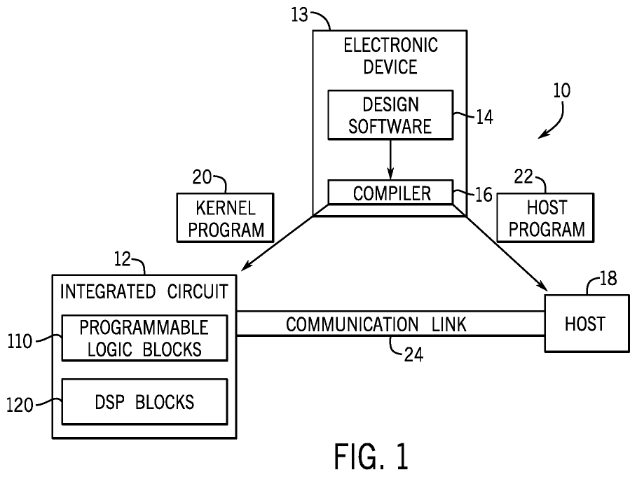

With the foregoing in mind, FIG. 1 illustrates a block diagram of a system 10 that may be used in configuring an integrated circuit 12 with such a DSP block. A designer may desire to implement digital signal processing functionalities on the integrated circuit 12 (e.g., a programmable logic device such as a field-programmable gate array (FPGA) or an application-specific integrated circuit (ASIC) that includes programmable logic circuitry). The integrated circuit 12 may include a single integrated circuit, multiple integrated circuits in a package, or multiple integrated circuits in multiple packages communicating remotely (e.g., via wires or traces). In some cases, the designer may specify a high-level program to be implemented, such as an OPENCL® program that may enable the designer to more efficiently and easily provide programming instructions to configure a set of programmable logic cells for the integrated circuit 12 without specific knowledge of low-level hardware description languages (e.g., Verilog, very high speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit 12.

In a configuration mode of the integrated circuit 12, a designer may use an electronic device 13 (e.g., a computer) to implement high-level designs (e.g., a system user design) using design software 14, such as a version of INTEL® QUARTUS® by INTEL CORPORATION. The electronic device 13 may use the design software 14 and a compiler 16 to convert the high-level program into a lower-level description (e.g., a configuration program, a bitstream). The compiler 16 may provide machine-readable instructions representative of the high-level program to a host 18 and the integrated circuit 12. The host 18 may receive a host program 22 that may be implemented by the kernel programs 20. To implement the host program 22, the host 18 may communicate instructions from the host program 22 to the integrated circuit 12 via a communications link 24 that may be, for example, direct memory access (DMA) communications or peripheral component interconnect express (PCIe) communications. In some embodiments, the kernel programs 20 and the host 18 may enable configuration of programmable logic blocks 110 on the integrated circuit 12. The programmable logic blocks 110 may include circuitry and/or other logic elements and may be configurable to implement a variety of functions, including finite impulse response (FIR) filtering, in combination with digital signal processing (DSP) blocks 120. In certain instances, the FIR filter may be decomposed into two or more individual filters. In an embodiment, the individual filters and/or the FIR filter may be symmetric filters. The DSP block 120 may implement the two or more decomposed FIR filters. In other instances, the two or more decomposed FIR filters may be implemented by programmable logic blocks 110. As further described herein, decomposing the FIR filter into two or more filters (e.g., sub-filter, partial filter, component filter) for implementation may reduce an amount of power consumed by the integrated circuit 12.

The designer may use the design software 14 to generate and/or to specify a low-level program, such as the low-level hardware description languages described above. Further, in some embodiments, the system 10 may be implemented without a separate host program 22. Thus, embodiments described herein are intended to be illustrative and not limiting.

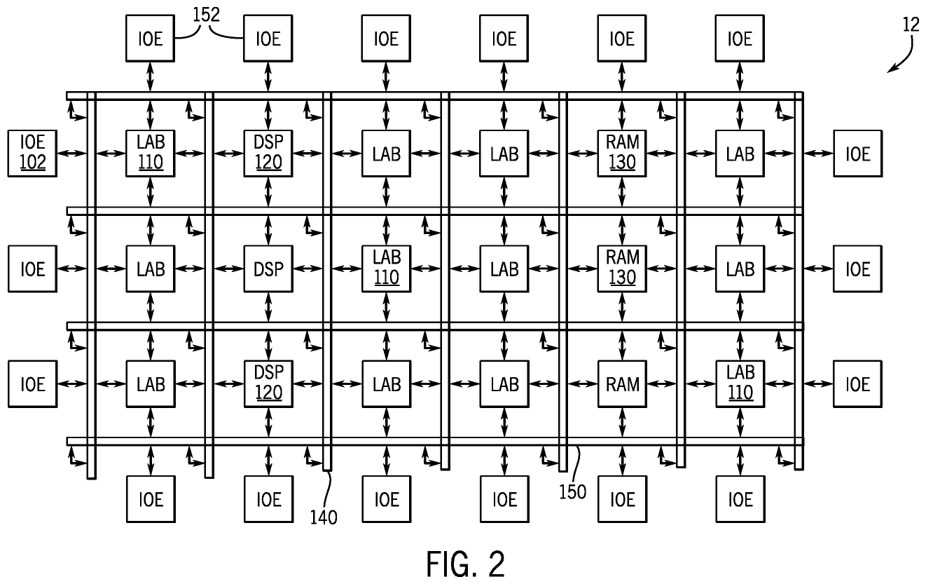

An illustrative embodiment of a programmable integrated circuit 12 such as a programmable logic device (PLD) that may be configured to implement a circuit design is shown in FIG. 2. As shown in FIG. 2, the integrated circuit 12 (e.g., a field-programmable gate array integrated circuit die) may include a two-dimensional array of functional blocks, including programmable logic blocks 110 (also referred to as logic array blocks (LABs) or configurable logic blocks (CLBs)) and other functional blocks, such as random-access memory (RAM) blocks 130 and digital signal processing (DSP) blocks 120, for example. Functional blocks such as LABs 110 may include smaller programmable regions (e.g., logic elements, configurable logic blocks, or adaptive logic modules) that receive input signals and perform custom functions on the input signals to produce output signals. LAB s 110 may also be grouped into larger programmable regions sometimes referred to as logic sectors that are individually managed and configured by corresponding logic sector managers. The grouping of the programmable logic resources on the integrated circuit 12 into logic sectors, logic array blocks, logic elements, or adaptive logic modules is merely illustrative. In general, the integrated circuit 12 may include functional logic blocks of any suitable size and type, which may be organized in accordance with any suitable logic resource hierarchy.

Programmable logic circuitry of the integrated circuit 12 may include programmable memory elements. The memory elements may be loaded with configuration data (also called programming data or configuration bitstream) using input-output elements (IOEs) 152. Once loaded, the memory elements respectively provide a corresponding static control signal that controls the operation of an associated functional block (e.g., LABs 110, DSP 120, RAM 130, or input-output elements 152).

In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The memory elements may use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory, configuration random-access memory (CRAM), or programmable memory elements. Programmable logic device (PLD) may be configured to implement a custom circuit design. For example, the configuration RAM may be programmed such that LABs 110, DSP 120, and RAM 130, programmable interconnect circuitry (e.g., vertical routing channels 140 and horizontal routing channels 150), and the input-output elements 152 form the circuit design implementation.

In addition, the programmable logic device may have input-output elements (IOEs) 152 for driving signals off of the integrated circuit 12 and for receiving signals from other devices. Input-output elements 152 may include parallel input-output circuitry, serial data transceiver circuitry, differential receiver and transmitter circuitry, or other circuitry used to connect one integrated circuit to another integrated circuit.

The integrated circuit 12 may also include programmable interconnect circuitry in the form of vertical routing channels 140 (i.e., interconnects formed along a vertical axis of the integrated circuit 100) and horizontal routing channels 150 (i.e., interconnects formed along a horizontal axis of the integrated circuit 100), each routing channel including at least one track to route at least one wire. If desired, the interconnect circuitry may include pipeline elements, and the contents stored in these pipeline elements may be accessed during operation. For example, a programming circuit may provide read and write access to a pipeline element.

Note that other routing topologies, besides the topology of the interconnect circuitry depicted in FIG. 1, are intended to be included within the scope of the present invention. For example, the routing topology may include wires that travel diagonally or that travel horizontally and vertically along different parts of their extent as well as wires that are perpendicular to the device plane in the case of three-dimensional integrated circuits, and the driver of a wire may be located at a different point than one end of a wire. The routing topology may include global wires that span substantially all of the integrated circuit 12, fractional global wires such as wires that span part of the integrated circuit 12, staggered wires of a particular length, smaller local wires, or any other suitable interconnection resource arrangement.

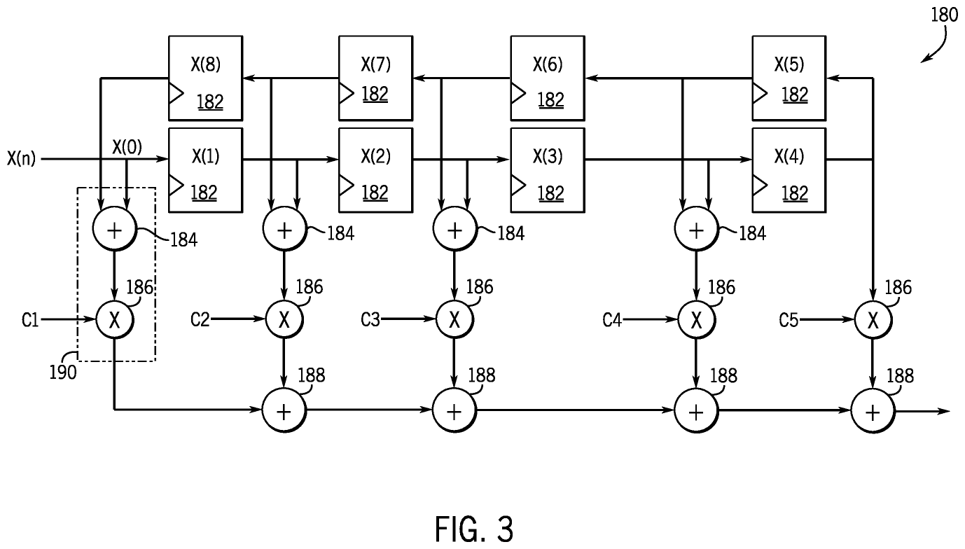

The integrated circuit 12 may be programmed to perform a wide variety of operations. One example shown in FIG. 3 is finite impulse response (FIR) filtering. For example, a FIR filter may be an asymmetric FIR filter in which weights applied to different taps may be different or, in the example of FIG. 3, may be a symmetric FIR filter 180 in which the weights are the same magnitude around some defined point. For example, a 15-tap FIR filter (where taps are indexed 1 . . . 15), may include weights with the same magnitude at indices 1 and 15, 2 and 14, 3 and 13, and so on, and tap 8 will be a single value in the middle. This can also be applied to filters with even number of taps, for example an 8 tap filter. In that case, taps 1, 2, 3, 4 will have the same weight magnitudes as taps 8, 7, 6, and 5, respectively. For a 16-tap FIR filter (where taps are indexed 0 . . . 15), the weights have the same magnitude at indices 0 and 15, 1 and 14, 2 and 13 . . . and so on.

In the example of FIG. 3, the symmetric FIR filter 180 receives an input signal x(n). The FIR filter 180 has 9 taps symmetric to a point x(4) of the signal x(n) when the first point in the x(n) signals is x(0). The x(n) signal traverses registers 182 that provide the tap points into a pre-adder 184 before the results enter a multiplier 186 to multiply by a weight value (here, coefficients C1, C2, C3, C4, or C5). The partial results are summed together in adders 188 to obtain the result of the filter 180. In some cases, the weights may have the same magnitude, but a different sign. In such cases, the pre-adder 184 may be configurable as a presubtractor.

Some support for symmetric filters is provided by the pre-adder 184 in front of the multiplier 186; however, in some embodiments, the calculations done by the pre-adder 184 may be performed using an additional multiplier. Some DSP blocks 120 may have 1 or 2 multipliers, although more multipliers are possible. The advantage of the method shown in FIG. 3 is that about half the number of multipliers (half+1 in the case of an odd length filter) are used to implement a symmetric FIR filter, compared to providing a multiplier 186 for each tap. Before continuing, it should be noted that the example of a symmetric FIR filter is purely illustrative.

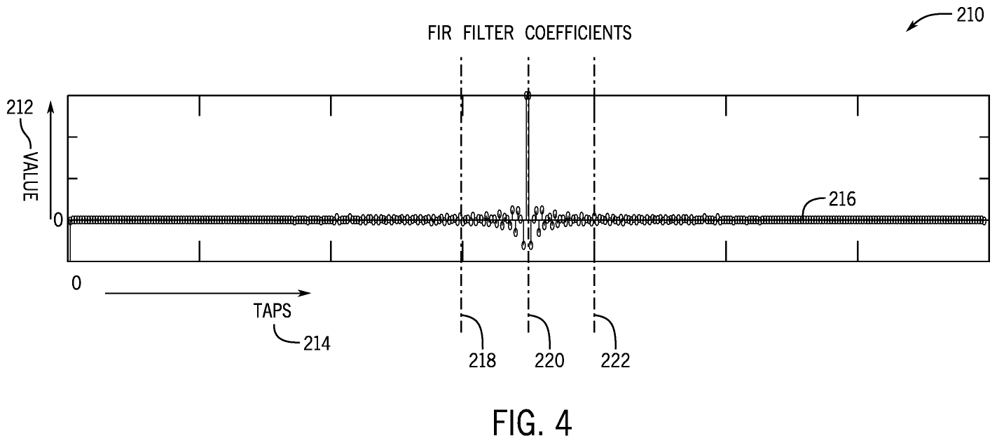

In one example, the FIR filter 180 may be decomposed into a first partial filter (e.g., sub-filter, component filter) and a second partial filter (e.g., sub-filter, component filter) based on filter coefficients, as described with respect to FIGS. 4-7. The outputs of the first partial filter and the second partial filter may be mathematically similar to the output of the FIR filter 180. In certain instances, the FIR filter 180 may have coefficients (e.g., C1, C2, C3) with large values at or about a center tap and the coefficient values may decrease towards the start or end of the taps. With the preceding in mind, FIG. 4 illustrates a graph 210 with coefficient values 212 in the FIR filter 180 over a number of taps 214. By way of illustrative example, the FIR filter 180 may be a 300-tap channel filter, although the FIR filter 180 may include any suitable number of taps, such as 8, 16, 32, 64, 100, 200, 500, 1000 or more. The FIR filter 180 may operate as a low pass filter, but any other suitable filter may be implemented (e.g., high-pass, passband, stopband, passband ripple, stopband attenuation).

The FIR filter 180 may include a coefficient value 212 over a tap 214. The coefficients value 212 may be small (e.g., zero or approximately zero) from taps 0 to 150 (e.g., point 218) and taps 200 (e.g., point 222) to 300, while the coefficients values 212 may be large from taps 151 to 199 (e.g., point 218 to point 222). In this way, a region for outer coefficients (e.g., from 0 to point 218, point 222 to end) and a region for inner coefficients (e.g., point 218 to point 222) may be defined. While the illustrated example uses a 300-tap filter, any suitable number of taps may be used to design the FIR filter. That is, the general trend described with respect to graph 210 may be used for any suitable number of taps. For example, a 16-tap filter may have a local maximum coefficient value at a center tap of 8. In another example, an 8-tap filter may have a local maximum coefficient value at a center tap of 4. It may be understood that a greater number of taps makes the FIR filter more selective since a larger sample for the filter is taken, but also increase an amount of hardware resources consumed by the filter.

In the graph 210, the coefficient values 212 over the number of taps 214 are illustrated by a curve 216. As illustrated by the curve 216, the coefficient values 212 may be zero or approximately zero at a first tap (e.g., 0) and a last tap. Starting at a point 218, the curve 216 may increase until a point 220, which may be a center tap value. In other words, the coefficient values 212 may increase to a local maximum value. At point 220, the curve 216 may reach a local maximum, or a highest coefficient value. That is, a maximum coefficient value may be associated with the center tap. Starting at point 220, the curve 216 may decrease until a point 222 where the curve 216 reaches zero or approximately zero. In other embodiments, the coefficient values 212 may stabilize at different values, such as −1, −0.5, 0.5, 1, and the like.

As illustrated by the graph 210, the curve 216 reaches the local maximum at the point 220. The coefficient value 212 immediately prior and immediately subsequent may be significantly lower than the local maximum at point 220. In this example, the coefficients values 212 may be large at or approximately around a center tap and the coefficients values 212 may be small immediately outside of the center tap. In other examples, the coefficient values 212 may be small at a first portion of the taps 214 and may be large at a second portion of the taps 214.

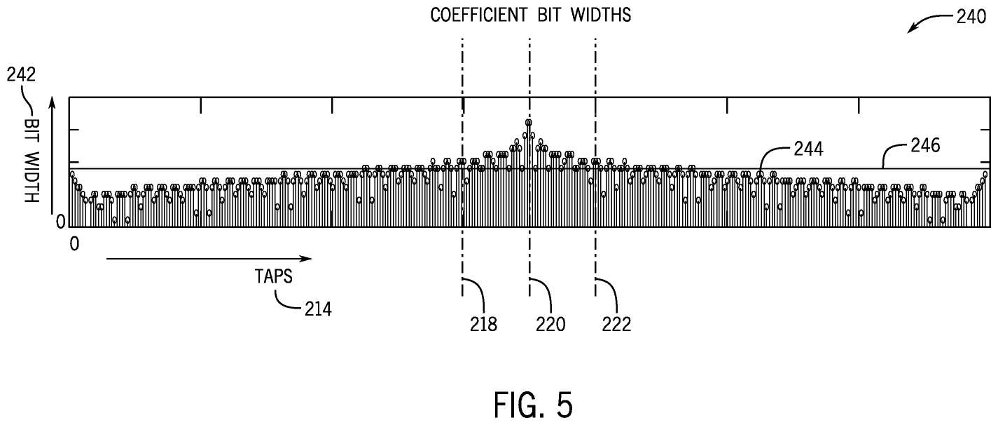

FIG. 5 illustrates a graph 240 with a number of bits (e.g., bit-width 242) that may describe a total number of bits to represent the coefficients of the FIR filter 180 over a number of taps 214. For example, the graph 240 includes a curve 244 illustrating a log(2) of the coefficient value 212 to determine the bit-width 242. The graph 240 also includes a line 246 illustrating a threshold bit-width (e.g., threshold value). For example, the threshold bit-width may be 9 bits. The coefficients at or below the threshold bit-width may be represented by 9 bits and the coefficients above the threshold bit-width may not be represented by 9 bits. In certain instances, the threshold bit-width may be 8 bits, 16 bits, or any suitable number of bits. As such, the coefficients at or below the threshold bit-width may be represented by 8 bits or 16 bits, while coefficients above the threshold bit-width may not be represented by 8 bits or 16 bits.

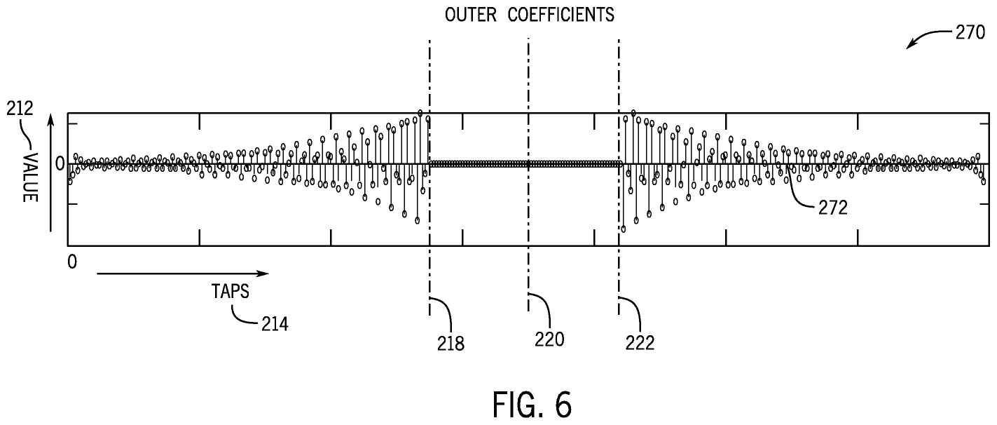

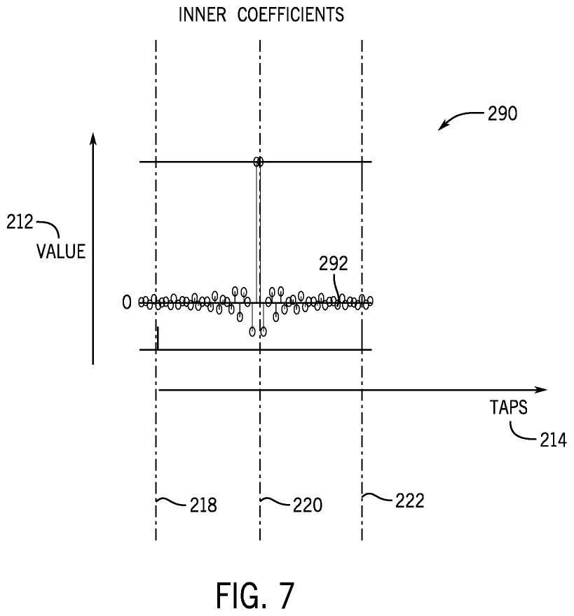

By way of example, the curve 244 illustrates the log(2) of the coefficients, which represents a bit-width 242 of the coefficient and the line 246 illustrates the threshold bit-width. As illustrated by the curve 244, the coefficients from taps 0 to taps at point 218 are at or below the line 246 and the coefficients from taps at point 222 to a last tap may also be at or below the line 246. The coefficients, as illustrated by curve 244, between the points 218 and 222 are above or substantially above the line 246. As such, the points 218 and 222 may be a threshold tap value. That is, many, most, or all of the tap values below point 218 may have coefficients below the threshold value and many, most, or all of the tap values above point 222 may also have coefficients above the threshold value. In certain embodiments, an amount of distortion may be acceptable to improve efficiency. For example, a user may define the amount of acceptable distortion. In this case, one or more tap values below the point 218 may include coefficients above the threshold bit-width that may be clipped and/or rounded to the threshold bit-width and one or more tap values above point 222 may include coefficients below the threshold bit-width. As further described with respect to FIGS. 6 and 7, the outer coefficients may be defined by tap values from 0 to point 218 and point 222 to a last tap, while the inner coefficients may be defined by tap values from point 218 to point 222. In an embodiment, the FIR filter 180 may be decomposed into a first partial filter including the outer coefficients and a second partial filter including the inner coefficients. Each of the partial filters may receive the same sample (e.g., data) and the outputs from each of the partial filters may be added to produce a mathematically similar output as the FIR filter 180. However, decomposing the FIR filter 180 into two partial filters may save resources and space on the integrated circuit 12. As such, the integrated circuit 12 may more efficiently process the sample. In certain instances, the first partial filter and the second partial filter may be symmetric FIR filters.

FIG. 6 illustrates a graph 270 with the coefficient values 212 over a number of taps 214. The graph 270 is substantially similar to the graph 210 described with respect to FIG. 4, except the coefficient values 212 from point 218 to point 222 are removed. As such, the scale for the coefficient values 212 may be different from the scale used in graph 210. That is, the scale may be increased by a factor of 10⁻³ to illustrate the coefficient values 212.

The graph 270 illustrates the outer coefficients, which are the coefficients with smaller values in comparison the coefficients around the center tap (e.g., point 220). The graph 270 includes a curve 272 illustrating the coefficient values 212 for the coefficients between taps 0 and point 218 and point 222 to a last tap (herein referred to as “outer coefficients”). The first partial filter may use 9-bits since the outer coefficients are small values. In this way, the first partial filter may be more efficient since the data bits passed through the first partial filter are smaller in comparison to data bits passed through the second partial filter.

FIG. 7 illustrates a graph 290 with the coefficient values 212 over a number of taps 214. The graph 290 includes a curve 292 illustrating the coefficients between the points 218 and 222 (herein referred to as “inner coefficients”). The second partial filter may be a short filter with taps starting at point 218 and ending at point 222. The second partial filter may use 16-bits since the inner coefficient values are large in comparison to the outer coefficient values. In this way, the FIR filter 180 may be decomposed into two partial filters based on the coefficient values. That is, a first partial filter may process outer coefficients using 9-bits coefficients for the outer taps and a second partial filter may process inner coefficients using 16-bit coefficients for the inner taps. Decomposing the FIR filter into two partial filters may increase an output precision and also increase efficiency of the FIR filter since the coefficients of each partial filter may use less data bits.

In certain instances, the FIR filter 180 may use output rounding to constrain a bit-width of the final output. It is generally understood that filters have a same input and output precision, however during operation, the precision may vary and be significantly higher. For example, multiplying a 16-bit sample with a 16-bit coefficient results in a 32-bit output. If the FIR filter 180 includes 300 taps, then the 32-bit output may be added resulting in a log₂(300)=9-bits of data growth. As a result, the output may 32-bits+9-bits=41-bits of data. The output may scaled to a desired output precision (e.g., 16-bits) by removing least significant bits (LSB). That is, all or most of the important data may be contained within a portion (e.g., top half) of the bits or the most significant bits (MSB). As such, the LSB may not include applicable information for the output.

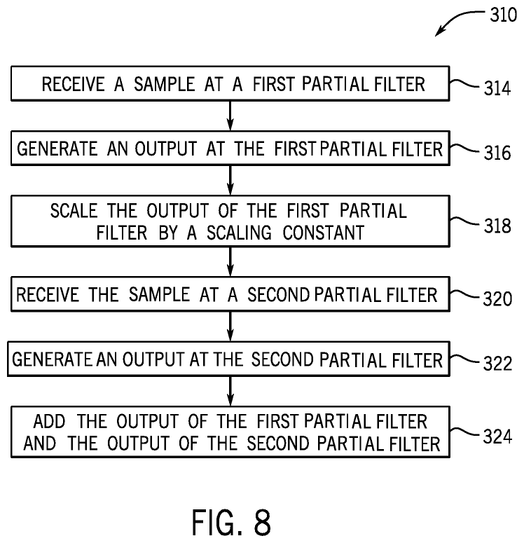

To reduce or eliminate data growth, the FIR filter 180 may be decomposed into two or more partial filters and the data contained within the LSB may be dropped for the output of each partial filter. FIG. 8 illustrates a flow chart of an example method 310 for passing a sample through two or more partial filters. For example, the first partial filter may include the outer coefficients while the second partial filter may include the inner coefficients. The outputs of the first partial filter and the second partial filter may be added to get a final output, which may be mathematically identical to the output of the FIR filter 180. Each of the partial filters may be implemented by the DSP blocks 120 and/or the programmable logic blocks 110 of the integrated circuit 12. In certain instances, the first partial filter may be implemented on the DSP block 120 and the second partial filter may be implemented on the programmable logic blocks 110, or vice versa. In other instances, the first partial filter and the second partial filter may be implemented on the DSP block 120.

At block 314, the sample may be received at a first partial filter. The sample may include an input signal, such as x(n) described with respect to FIG. 3. In certain instances, the host 18 may receive the sample for processing by the first partial filter (e.g., as implemented by the DSP block 120 or the programmable logic blocks 110). A first partial filter (e.g., sub-filter or component filter of the FIR filter) may receive the sample and multiple the sample by a coefficient (e.g., C1, C2, C3) and to get an output at block 316. As described herein, multiplying a 16-bit sample by a 16-bit coefficient may generate a 32-bit output. As such, at block 318, the output of the first partial filter may be scaled by a scaling constant. Multiplying the output by the scaling constant may be important to maintain a correct output precision. For example, the output of the first partial filter may be scaled by 2¹⁶ when the output precision is 16-bits. In another example, the output of the first partial filter may be scaled by 2⁸ when the output precision is 8-bits. In this way, the LSB of the output is dropped and the MSB is retailed. As described herein, the MSB may contain relevant data for the final output, and in certain instances, the LSB may not contain or add additional data. In this way, a bit-width of the output may be constrained and data growth may be reduced.

At block 320, the sample may be received at a second partial filter (e.g., sub-filter or component filter of the FIR filter). The second partial filter may pass the sample through with the inner coefficients to generate an output at block 322. In certain instances, the output of the second partial filter may be bit-shifted based on the output precision. For example, the output of the second partial filter may be multiplied by the scaling constant to constrain a bit-width of the output. In this way, data growth from the data being passed through multiple filters may be constrained to the desired bit-width and resources of the integrated circuit 12 and/or the host 18 may be saved.

At block 324, the outputs from the first partial filter and the second partial filter are added to get the final output. With the correct scaling constants, the final output may be mathematically similar or substantially similar to the output of the FIR filter 180. However, decomposing the FIR filter 180 into two partial filters may reduce an amount of hardware resources consumed and reduce a space occupied. In this way, digital signal processing procedures may be improved.

The method 310 includes various steps represented by blocks. Although the flow chart illustrates the steps in a certain sequence, it should be understood that the steps may be performed in any suitable order and certain steps may be carried out simultaneously, where appropriate. Further, certain steps or portions of the method 310 may be performed by separate systems or devices.

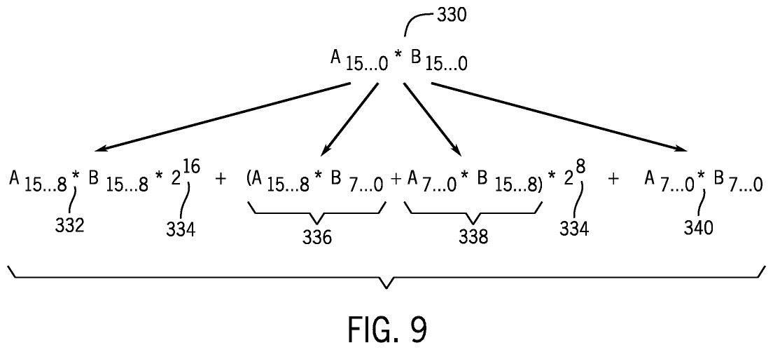

FIG. 9 illustrates a block diagram of a one-tap FIR filter 330 decomposed into four partial filters 332, 336, 338, and 340. In an embodiment, a filter (e.g., multipliers) of n-bits can be decomposed into 4 partial filters (e.g., multipliers) of k-bits and m-bits, where k+m=n. If k=m=n/2, then an n-bit filter may be decomposed into four m-bit filters. For example, a 16-bit filter may be decomposed into four 8-bit filters, as illustrated by Equation 1 below:

A_{15...0}*B_{15... 0}=A_{15...8}*B_{15...8}*2¹⁶+(A_{15...8}*B_{7...0}+A_{7...0}* B_{15...8})*2⁸+A_{7...0}*B_{7...0} (1)

Equation 1 describes a single filter (e.g., multiplier), which may be interpreted as a one-tap FIR filter 330 with a sample A and a coefficient B. The one-tap FIR filter 330 may be a 16-bit filter that takes in the sample A (having a 16-bits as represented by 15...0) and multiples the sample A with the coefficient B (having a 16-bits). As such, the output may be a 32-bits. However, in other embodiments, the FIR filter 330, the sample A, and the coefficient B may be any suitable bit-width, such as 6-bits, 7-bits, 8-bits, 9-bits, 10-bits, 32-bits, and so on.

Returning to Equation 1, the one-tap FIR filter 330 may be decomposed into four 8-bit partial filters. A first partial filter 332 may be represented by A_{15...8}*B_{15...8}. That is, the first partial filter 332 may pass the upper bits (e.g., bits 8 to 15) from the sample A and the upper bits from the coefficient B. In other words, the first partial filter 332 may pass through a top 8 bits from the sample A and a top 8 bits from the coefficient B for an output. In this way, the first partial filter 332 may be an 8-bit filter rather than a 16-bit filter. The output of the first partial filter 332 may be multiplied by a scaling constant 334 (e.g., desired output precision). That is, the first partial filter 332 intakes two 8-bit values and outputs 16-bits. The output may be scaled by 2¹⁶ so that the output may be a 32-bit value, which ensures the final output precision is at desired bit-width.

A second partial filter 336 may be represented by A_{15...8}*B_{7...0} and a third partial filter 338 may be represented by A_{7...0}*B_{15...8}. That is, the second partial filter 336 passes through the upper bits from the sample A and lower bits from the coefficient B, while the third partial filter 338 passes through the lower bits from the sample A and the upper bits from the coefficient B. The outputs from the second partial filter 336 and the third partial filter 338 are added. For example, two 8-bit values may be added, resulting in a 16-bit output. The output may be multiplied by the scaling constant 334 by 2⁸ so that the final output may be 32-bits.

A fourth partial filter 340 may be represented by A_{7...0}*B_{7...0}, which passes through the lower bits for the sample A and the lower bits for the coefficient B. The fourth partial filter 340 may not be multiplied by the scaling constant 334. The outputs of each of the partial filters 332, 336, 338, and 340 may be added together for a final output. When multiplied to the correct scaling constant (e.g., 2¹⁶, 2⁸), the output from each partial filter 332, 336, 338, and 340 may be added. The final output may be mathematically identical (e.g., substantially similar) to the output of the original 16-bit FIR filter 330 with 16-bits of data and coefficients.

In this way, the original 16-bit FIR filter 330 may be decomposed into four individual 8-bit partial filters 332, 336, 338, and 340. Additionally or alternatively, the fourth partial filter 340 may be optimized away (e.g., dropped). As illustrated in Equation 1, the output of the first partial filter 332 is scaled by 2¹⁶ whereas the fourth partial filter 340 is not. It may be understood that the fourth partial filter 340 only contributes a value to the final output that is below the LSB of the first partial filter 332 and below an LSB of the final output. As such, in certain embodiments, the fourth partial filter 340 may be removed. In this way, the filter may be decomposed into three smaller filters with smaller bit-widths, which may consume fewer resources for calculations.

Adding to Equation 1, a second sample C and a second coefficient D may be added, thereby creating a two-tap FIR filter. The second sample C may be sample A delayed by one cycle. The addition of the second sample C and the second coefficient D may be equivalent to a sum of two multiplications. Equation 2, below, illustrates the two-tap FIR filter:

A_{15...0}*B_{15...0}+C_{15...0}*D_{15...0}=A_{15...8}*B_{15...8}2¹⁶+(A_{15...8}*B_{7...0}+A_{7...0}*B_{15...8}) *2⁷+A_{7...0}*B_{7...0}+C_{15...8}*D_{15...8}*2¹⁶+(C_{15...8}*D_{7...0}+C_{7...0}*D_{15...8})*2⁸+C_{7...0}*D_{7...0} (2)

By way of example, the sample A, the coefficient B, the sample C, and the coefficient D may have a 16-bit width (as represented by 15...0), respectively. As such, the first partial filter 332 may be represented by A_{15...8}*B_{15...8}*2¹⁶ and C_{15...8}*D_{15...8}*2¹⁶, which includes the top half bits of the sample A, the coefficient B, the sample C, and the coefficient D. In the illustrated example, the top half bits are the top 8-bits of data (as represented by 15...8). The second partial filter 336 may be represented by A_{15...8}*B_{7...0} and C_{15...8}*D_{7...0}, the third partial filter 338 may be represented by A_{7...0}*B_{15...8} and C_{7...0}*D_{15...8}, the fourth partial filter 340 may be represented by A_{7...0}*B_{7...0} and C_{7...0}*D_{7...0}. The fourth partial filter 340 passes through the bottom half bits (as represented by 7...0). In this way, the 16-bit FIR filter 330 may be decomposed into four 8-bit partial filters. In certain instances, each of the partial filters 332, 336, 338, and 340 may be a symmetric FIR filter. While the illustrated examples of Equation 1 and Equation 2 uses unsigned data, the FIR filters may process signed data.

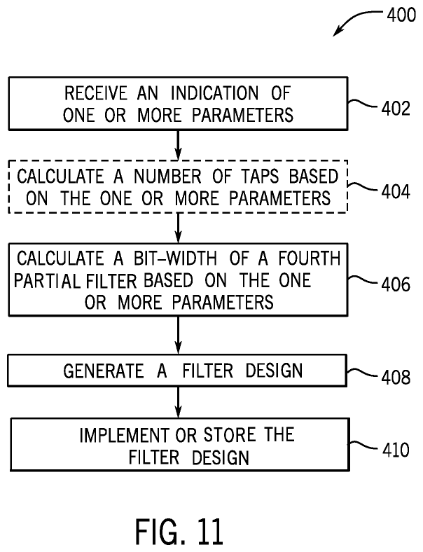

Equation 2 for the two-tap FIR filter may be transformed into a general form, as shown below in Equation 3. FIG. 11 illustrates a block diagram of a FIR filter decomposed into four individual partial filters. In general form, the Equation 3 includes the samples s, the coefficients c, a number of taps N, an index n, a sample index t, and a signal yₜ.

$${y}_{t , 15 … 0} = {{\sum }_{n = 1}}^{N} ( {c}_{n , 15 … 0} * {s}_{n - t , 15 … 0} ) = {2}^{16} * {{\sum }_{n = 1}}^{N} {c}_{n , 15 … 8} * {s}_{n - t , 15 … 8} * {2}^{8} * ( {\sum }^{N} {{c}_{n , 15 … 8}}_{n = 1} {*}_{n - t ,} {s}_{7 … 0} + {\sum }^{N} {{c}_{n , 7 … 0}}_{n = 1} * {s}_{n - t , 15 … 8} ) {+}^{N} \sum {{c}_{n , 7 … 0} * {s}_{n - t , 7 … 0}}_{n = 1} \qquad ( 3 )$$

The FIR filter 360 (e.g., non-decomposed FIR filter) may be represented by y_{t,15...0}=Σₙ₌₁^{N}(c_{n,15...0}×s_{n-t,15...0}) That is, the FIR filter 360 may pass through the sample s and multiple the sample s by coefficient c to output the signal yₜ. The output signal yₜ may have a bit-width of 16-bits (as represented by 15...0). As discussed herein, filters may be resource-intensive, as such decomposing the filter into two or more partial filters may reduce an amount of resources consumed each of the partial filters while maintaining precise outputs.

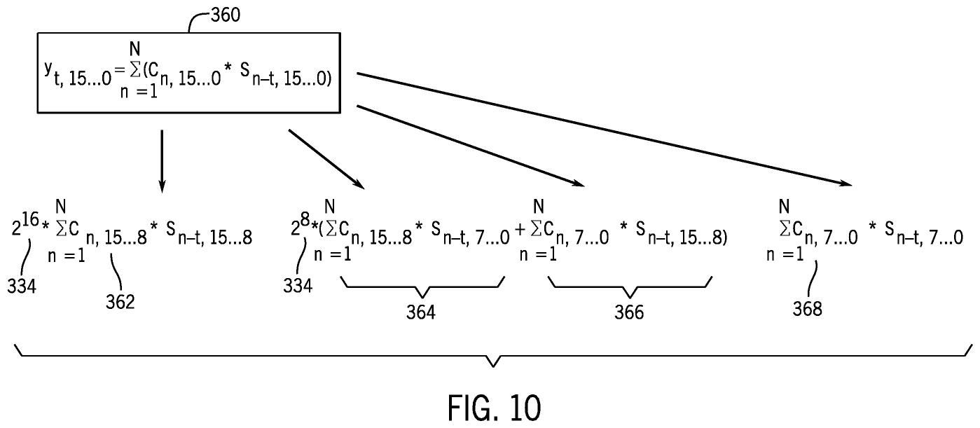

Returning to FIG. 11, the FIR filter 360 may be decomposed into four 8-bit filters. A first partial filter 362 may be represented by Σₙ₌₁^{N}c_{n,15...8}×s_{n-t,15...8}. That is, the first partial filter 362 may pass through a top 8-bits of the sample s and a top 8-bits of the coefficient c to get an output. The output may be multiplied by the scaling constant 334 before being added to the outputs of other three partial filters 364, 366, and 368. For example, the scaling constant may be 2¹⁶. The mathematically representation of the first partial filter 363 may be a generalized form of the mathematical representation of the first partial filter 332 described with respect to FIG. 10.

The second partial filter 364 may be represented by Σₙ₋₁^{N}c_{n,15...8}×s_{n-t,7...0} and the third partial filter 366 may be represented by Σₙ₌₁^{N}c_{n,7...0}×s_{n-t,15...8}. The outputs of the second partial filter 364 and the third partial filter 366, respectively, may be added prior to being multiplied by the scaling constant 334. The fourth partial filter 368 may be represented by Σₙ₌₁^{N}c_{n,7...0}×s_{n-t,7...0}. The outputs of each partial filter 362, 364, 366, and 368 may be added (e.g., summed) together to get the final output. The final output may be mathematically identical (e.g., substantially similar) to the output of the FIR filter 360.

As illustrated by Equation 3, the first partial filter 362 is multiplied by the scaling constant 334 of 2¹⁶ and the combined outputs of the second partial filter 364 and the third partial filter 364 are multiplied by the scaling constant 334 of 2⁸, while the fourth partial filter 368 may not be multiplied by the scaling constant. In this way, the output of the first partial filter 263 is 16-bits larger than the output of the fourth partial filter 368. As such, the output of the fourth partial filter 368 may be below the LSB of the first partial filter 362. Moreover, the output of the fourth partial filter 368 is below the LSB of the final output. As such, in an embodiment, the fourth partial filter 368 may be removed, thereby reducing an amount of space occupied by the partial filters. For example, the size may be reduced by ¼ in comparison to the FIR filter 360 (e.g., non-decomposed FIR filter).

In an embodiment, the fourth partial filter 368 may be removed from Equation 3. In certain instances, an error may be introduced by removing the fourth partial filter 368, however the output of the fourth partial filter 368 may be small in comparison to the output of the first partial filter 362. As such, the error may be minimal. As such, Equation 4 may be simplified from four partial filters to three partial filters.

$${y}_{t , 15 … 0} = {{\sum }_{n = 1}}^{N} {c}_{n , 15 … 0} * {s}_{n - t , 15 … 0} = {2}^{16} * {\sum }^{N + m / 2} {{c}_{n , 15 … 8}}_{n = N - m / 2} * {s}_{n - t , 15 … 8} * {2}^{8} * ( {\sum }^{N + m / 2} {{c}_{n , 15 … 8} *}_{n = M - m / 2} {s}_{n - t , 7 … 0} {+}^{N} \sum {c}_{{n , 7 … 0}_{n = 1}} * {s}_{n - t , 15 … 8} ) \qquad ( 4 )$$

In certain instance, if the coefficients are 8-bits or smaller, then the term c_{n,15...8} may be zero or effectively equivalent to zero for the corresponding taps. That is, the outer coefficients may be small in comparison to the inner coefficients. For example, the first partial filter 362 applies to outer taps not the inner taps, as such the coefficient may effectively be zero. As such, the first partial filter 362 starts at a few taps below a middle point M and a few taps above the middle point M. In other words, the first partial filter 362 passes through the inner coefficients. In another example, the MSB of the third partial filter 364 may be zero or substantially close to zero, as such the output may be effectively zero. The third partial filter 364 may also pass through the inner coefficients. As such, the first partial filter 362 and the second partial filter 364 may be short filters (e.g., partial number of taps). The third partial filter 366 may be a long filter (e.g., full number of taps). As illustrated by Equation 4, the third partial filter 366 starts from a first tap and stops at a last tap. In other words, if a FIR filter is N taps long, but only a middle M taps exceeds 8-bits, then a short M-tap filter for the middle taps may be represented. In this way, the FIR filter 360 may be decomposed into one long partial filter (e.g., with a full number of taps) and two short partial filters (e.g., less than a full number of taps). A size of the partial filters 362, 364, and 366 may be reduced by ½ in comparison of to a size of the non-decomposed FIR filter 360. Accordingly, the decomposed filter may reduce an amount of resources consumed during operation and also reduce an amount of space occupied on the integrated circuit 12.

Furthermore, decomposing the FIR filter into two or more partial filters helps constrain the data width or coefficient width by scaling the output of each partial filter. For example, FPGAs may receive a data chain and the data width and/or the coefficient width may exceed a native multiplier width of 18-bits. As such, the data chain may be received by each of the partial filters, multiplied with the coefficients, and the output may be scaled to a desired output precision. As such, processing the data chain may not result in data growth, rather each output is scaled to the desired output precision prior to adding. In this way, resources on the FPGA may be conserved.

With the foregoing in mind, FIG. 11 illustrates a flow chart of an example method 400 for generating a decomposed filter design, such as including the partial filters 362, 364, and 366. The decomposed filter design may implemented into new and/or existing circuitry. For example, the decomposed filter design may be implemented into the DSP blocks 120 described with respect to FIG. 2 and/or the integrated circuit 12. In another example, the decomposed filter design may be implemented in a register-transfer logic (RTL) of the integrated circuit 12. Additionally or alternatively the RTL may be implemented in an application specific integrated circuit (ASIC). In another example, the decomposed filter design may include a simulation model and/or an implementation tool with two or more partial filters. In certain instances, the host 18 may be used to generate (e.g., create, program, implement) the decomposed filter design. For example, the host 18 may receive filter specification (e.g., parameters, user input) and generate the FIR filter, such as with the partial filters, based on the specification.

With the foregoing in mind, at block 402, the host 18 may receive an indication of one or more parameters. For example, a user may input one or more parameters for generating a filter design and/or filter tool (e.g., FIR IP tool, FIR filter design). The parameters may include an input precision, an output precision, a number of taps, a length of the filter, a bit-width, a data width, a number of bits for each coefficient, and the like. In certain instances, the user may input a frequency for filtering and the host 18 may determine an input precision, an output precision, and a number of coefficients for the filter design. In other instances, the user may input a number of taps or coefficients and the host 18 may determine the input precision, the output precision, and the like.

In certain instances, the user may not input a number of taps for the filter design. As such, the host 18 may calculate a number of taps based on the one or more parameters, at block 404. For example, based on the input precision and the output precision, the host 18 may calculate the number of taps for the filter design. In other instances, the user may input the number of taps, as such the method may skip block 404 and proceed to block 406.

At block 406, the host 18 may calculate a bit-width of the fourth partial filter (e.g., fourth partial filter 368 described with respect to FIG. 10) based on the one or more parameters. Based on the output precision, the host 18 may derive a data width (e.g., bit-width) of the fourth partial filter. Additionally or alternatively, the host 18 may derive a length of the short filters (e.g., first partial filter 362 described with respect to FIG. 10, second partial filter 364 described with respect to FIG. 10) based on a number of pre-determined bit-width for each coefficient.

At block 408, the host 18 may generate a filter design. For example, the filter design may be a FIR filter design including a bit accurate simulation model and/or implementation code. For example, the host 18 may determine a data width of a first partial filter, a second partial filter, or a combination thereof based on the parameters. The host 18 may combine the first partial filter and the second partial filter to generate the filter design. For example, the filter design may include a first partial filter passing the outer coefficients and a second partial filters passing the inner coefficients. In another example, the filter design may include four partial filters. Still in another example, the filter design may include three partial filters, such as one long filter and two short filters. In certain instances, the host 18 may compare a size of error of the generated filter design including the partial filters to a size of error of a traditional filter design, such as a FIR filter design.

At block 410, the host 18 may implement and/or store the filter design. For example, the host 18 may program the DSP block 120 and/or the programmable logic blocks 110 with the generated filter design (e.g., including the partial filters). In another example, the host 18 may store the filter design in the host program 22. Additionally or alternatively, the host 18 may generate a notification displaying the error between the generated filter design and the traditional filter design. As such, the user may determine if the error may be acceptable and input a response (e.g., accept, deny). In certain instances, the notification may also display resource estimates, such as an amount of resources used by the generated filter design. In this way, the user may make an informed decision regarding the generated filter design.

The method 400 includes various steps represented by blocks. Although the flow chart illustrates the steps in a certain sequence, it should be understood that the steps may be performed in any suitable order and certain steps may be carried out simultaneously, where appropriate. Further, certain steps or portions of the method 400 may be performed by separate systems or devices.

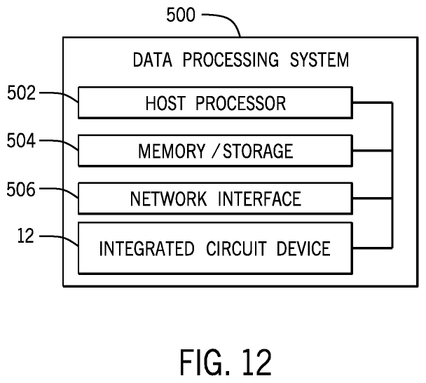

The integrated circuit system 12 may be a component included in a data processing system, such as a data processing system 500, shown in FIG. 12. The data processing system 500 may include the integrated circuit system 12 (e.g., a programmable logic device), a host processor 502, memory and/or storage circuitry 504, and a network interface 506. The data processing system 500 may include more or fewer components (e.g., electronic display, user interface structures, application specific integrated circuits (ASICs)). The integrated circuit 12 may be used to efficiently implement a filter (such as the FIR filter 360 described with respect to FIG. 10) that has been decomposed into two or more partial filters or perform complex multiplication. The host processor 502 may include any of the foregoing processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams, mapping function) for programming the integrated circuit system 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]...” or “step for [perform]ing [a function]...”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

Example Embodiment 1. An integrated circuit comprising digital filter circuitry comprising a first partial filter comprising a first number of taps corresponding to coefficients of a first bit depth and a second partial filter comprising a second number of taps corresponding to coefficients of a second bit depth.

Example Embodiment 2. The integrated circuit of example embodiment 1, wherein first number of taps is greater than the second number of taps.

Example Embodiment 3. The integrated circuit of example embodiment 1, wherein the first bit depth is less than the second bit depth.

Example Embodiment 4. The integrated circuit of example embodiment 1, comprising a third partial filter comprising a third number of taps corresponding to coefficients of a third bit depth.

Example Embodiment 5. The integrated circuit of example embodiment 4, comprising a first output comprising an output of the second partial filter and an output of the third partial filter are summed and scaled by a first scaling constant.

Example Embodiment 6. The integrated circuit of example embodiment 5, wherein an output of the first partial filter is scaled by a second scaling constant and summed with the first output, wherein the first scaling constant and the scaling constant are different.

Example Embodiment 7. The integrated circuit of example embodiment 4, comprising a fourth partial filter comprising a fourth number of taps corresponding to coefficients of a fourth bit depth.

Example Embodiment 8. The integrated circuit of example embodiment 7, wherein the fourth bit depth is the same as the third bit depth, and wherein the first bit depth is the same as the second bit depth.

Example Embodiment 9. The integrated circuit of example embodiment 7, wherein an output of the fourth partial filter is summed with an output of the first partial filter, an output of the second partial filter, and an output of the third partial filter.

Example Embodiment 10. The integrated circuit of example embodiment 1, wherein the first partial filter and the second partial filter are symmetric finite impulse response filters.

Example Embodiment 11. An integrated circuit comprising a finite impulse response filter of a higher bit-width formed from multiple sub-filters of a lower bit-width.

Example Embodiment 12. The integrated circuit of example embodiment 11, wherein the multiple sub-filters comprise a first sub-filter and a second sub-filter, wherein the first sub-filter comprises a first plurality of coefficients with a first bit-width above a threshold bit-width and the second sub-filter comprises a second plurality of coefficients with a second bit-width below the threshold bit-width.

Example Embodiment 13. The integrated circuit of example embodiment 12, wherein an output from the first sub-filter and an output from the second sub-filter are summed, and wherein the summed output is equivalent to an output of the finite impulse response filter.

Example Embodiment 14. The integrated circuit of example embodiment 11, comprising a first sub-filter of the multiple sub-filters comprising a first plurality of coefficients and a first scaling constant, a second sub-filter of the multiple sub-filters comprising a second plurality of coefficients, and a third sub-filter of the multiple sub-filters comprising a third plurality of coefficients, wherein an output of the second sub-filter is summed with an output of the third sub-filter to create a summed output.

Example Embodiment 15. The integrated circuit of example embodiment 14, wherein the summed output is scaled by a second scaling constant, and wherein the second scaling constant is different from the first scaling constant.

Example Embodiment 16. The integrated circuit of example embodiment 14, wherein the first plurality of coefficients are the same as the second plurality of coefficients.

Example Embodiment 17. The integrated circuit of example embodiment 11, wherein a summed output from the multiple sub-filters is equivalent to an output of the finite impulse response filter.

Example Embodiment 18. Digital processing circuitry, comprising a first sub-filter comprising a first number of taps corresponding to coefficients of a first bit depth and configurable to receive a first portion of a sample to generate a first output, a second sub-filter comprising a second number of taps corresponding to coefficients of a second bit depth and configurable to receive a second portion of a sample to generate a second output, and a third sub-filter comprising a third number of taps corresponding to coefficients of a third bit depth and configurable to receive a third portion of a sample to generate a third output.

Example Embodiment 19. The digital processing circuitry of example embodiment 18, wherein the coefficients of the first bit depth and the coefficients of the second bit depth are above a threshold bit depth, and wherein the coefficients of the third bit depth are below the threshold bit depth.

Example Embodiment 20. The digital processing circuitry of example embodiment 18, wherein the third number of taps of the third sub-filter is greater than the first number of taps of the first sub-filter.

What is claimed is:

1. An integrated circuit comprising:
digital filter circuitry comprising:
a first partial filter comprising a first number of taps corresponding to coefficients of a first bit depth; and
a second partial filter comprising a second number of taps corresponding to coefficients of a second bit depth.

2. The integrated circuit of claim 1, wherein first number of taps is greater than the second number of taps.

3. The integrated circuit of claim 1, wherein the first bit depth is less than the second bit depth.

4. The integrated circuit of claim 1, comprising a third partial filter comprising a third number of taps corresponding to coefficients of a third bit depth.

5. The integrated circuit of claim 4, comprising a first output comprising an output of the second partial filter and an output of the third partial filter are summed and scaled by a first scaling constant.

6. The integrated circuit of claim 5, wherein an output of the first partial filter is scaled by a second scaling constant and summed with the first output, wherein the first scaling constant and the scaling constant are different.

7. The integrated circuit of claim 4, comprising a fourth partial filter comprising a fourth number of taps corresponding to coefficients of a fourth bit depth.

8. The integrated circuit of claim 7, wherein the fourth bit depth is the same as the third bit depth, and wherein the first bit depth is the same as the second bit depth.

9. The integrated circuit of claim 7, wherein an output of the fourth partial filter is summed with an output of the first partial filter, an output of the second partial filter, and an output of the third partial filter.

10. The integrated circuit of claim 1, wherein the first partial filter and the second partial filter are symmetric finite impulse response filters.

11. An integrated circuit comprising:
a finite impulse response filter of a higher bit-width formed from multiple sub-filters of a lower bit-width, wherein the multiple sub-filters comprise:
a first sub-filter, wherein the first sub-filter comprises a first plurality of coefficients with a first bit-width, and
a second sub-filter, wherein the second sub-filter comprises a second plurality of coefficients with a second bit-width.

12. The integrated circuit of claim 11, wherein the first bit-width is above a threshold bit-width and the second bit-width is below the threshold bit-width.

13. The integrated circuit of claim 12, wherein an output from the first sub-filter and an output from the second sub-filter are summed, and wherein the summed output is equivalent to an output of the finite impulse response filter.

14. The integrated circuit of claim 11, wherein the first sub-filter of the multiple sub-filters comprises a first scaling constant, wherein the multiple sub-filters comprise a third sub-filter of the multiple sub-filters comprising a third plurality of coefficients, wherein an output of the second sub-filter is summed with an output of the third sub-filter to create a summed output.

15. The integrated circuit of claim 14, wherein the summed output is scaled by a second scaling constant, and wherein the second scaling constant is different from the first scaling constant.

16. The integrated circuit of claim 14, wherein the first plurality of coefficients is the same as the second plurality of coefficients.

17. The integrated circuit of claim 11, wherein a summed output from the multiple sub-filters is equivalent to an output of the finite impulse response filter.

18. Digital processing circuitry, comprising:
a first sub-filter comprising a first number of taps corresponding to coefficients of a first bit depth and configurable to receive a first portion of a sample to generate a first output;
a second sub-filter comprising a second number of taps corresponding to coefficients of a second bit depth and configurable to receive a second portion of a sample to generate a second output; and
a third sub-filter comprising a third number of taps corresponding to coefficients of a third bit depth and configurable to receive a third portion of a sample to generate a third output.

19. The digital processing circuitry of claim 18, wherein the coefficients of the first bit depth and the coefficients of the second bit depth are above a threshold bit depth, and wherein the coefficients of the third bit depth are below the threshold bit depth.

20. The digital processing circuitry of claim 18, wherein the third number of taps of the third sub-filter is greater than the first number of taps of the first sub-filter.
